(19) United States
(12) Patent Application Publication
(10) Pub. No.: US 2026/0098336 A1
(43) Pub. Date: Apr. 9, 2026

(54) METAL CARBIDE FILMS AND RELATED DEVICES AND RELATED METHODS

(71) Applicant: ENTEGRIS, INC., Billerica, MA (US)

(72) Inventors: Robert L. Wright, JR., Newtown, CT (US); Bryan C. Hendrix, Danbury, CT (US)

(21) Appl. No.: 19/344,177

(22) Filed: Sep. 29, 2025

Related U.S. Application Data
(60) Provisional application No. 63/703,759, filed on Oct. 4, 2024.

(51) Int. Cl. C23C 16/32; C23C 16/14; C23C 16/455; H01L 21/64

(52) U.S. Cl. CPC C23C 16/32; C23C 16/14; C23C 16/45553; H10P 95/00

(57) ABSTRACT

Metal carbide films and related devices and related methods are provided herein. A device comprises a substrate and a metal carbide film located on the substrate. The metal carbide film comprises at least one of a molybdenum, a tungsten, or any combination thereof. The metal carbide film comprises a residual chlorine component. The metal carbide film has a carbon content of at least 10% based on a total composition of the metal carbide film.

### CROSS-REFERENCE TO RELATED APPLICATIONS

This application claims the benefit under 35 USC 119 of U.S. Provisional Ser. No. 63/703,759 , filed Oct. 4, 2024, the disclosure of which is hereby incorporated herein by reference in its entirety.

### FIELD

The present disclosure relates to metal carbide films and related devices and related methods.

### BACKGROUND

Devices and components thereof are sometimes damaged during semiconductor fabrication processes.

### SUMMARY

Some embodiments relate to a device. In some embodiments, the device comprises a substrate. In some embodiments, the device comprises a metal carbide film located on the substrate. In some embodiments, the metal carbide film comprises at least one of a molybdenum, a tungsten, or any combination thereof. In some embodiments, the metal carbide film comprises a residual chlorine component. In some embodiments, the metal carbide film has a carbon content of at least 30% based on a total composition of the metal carbide film.

Some embodiments relate to a method. In some embodiments, the method comprises obtaining a carbon source. In some embodiments, the method comprises obtaining a metal chloride precursor. In some embodiments, the method comprises heating the metal chloride precursor and the carbon source to form a vapor. In some embodiments, the method comprises contacting a substrate with the vapor to form a metal carbide film. In some embodiments, the metal carbide film comprises a residual chlorine component. In some embodiments, the metal carbide film has a carbon content of at least 30% based on a total composition of the metal carbide film.

Some embodiments relate to a method. In some embodiments, the method comprises obtaining a substrate. In some embodiments, the method comprises forming a metal carbide film on the substrate. In some embodiments, the metal carbide film comprises at least one of a molybdenum, a tungsten, or any combination thereof. In some embodiments, the metal carbide film comprises a residual chlorine component. In some embodiments, the metal carbide film has a carbon content of at least 30% based on a total composition of the metal carbide film. In some embodiments, the method comprises obtaining a metal precursor. In some embodiments, the method comprises heating the metal precursor to form a vapor. In some embodiments, the method comprises contacting the vapor with the metal carbide film to form a metal layer.

### DRAWINGS

FIG. 1 is a flowchart of a method for forming a metal carbide film, according to some embodiments.

FIG. 2 is a is a flowchart of a method for forming a metal layer on a metal carbide film, according to some embodiments.

FIG. 3 is a graphical representation of an ALD metal carbide film deposition using acetylene and hydrogen, according to some embodiments.

FIG. 4 is a graphical representation of an ALD metal carbide film deposition using acetylene without hydrogen, according to some embodiments.

FIG. 5 is a Secondary Ion Mass Spectrometry (SIMS) showing a high concentration of carbon content in a metal carbide film along a depth, according to some embodiments.

FIG. 6 is a Secondary Ion Mass Spectrometry (SIMS) showing a low concentration of carbon content in a metal carbide film along a depth, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “contacting” refers to bringing two or more components into immediate or close proximity, or into direct contact.

As used herein, the term “step coverage” refers to a ratio of a thickness of a film on a first surface of a substrate to a thickness of the film on a second surface of the substrate. In some embodiments, the first surface of the substrate, the second surface of the substrate, and the third surface of the substrate are different. For example, in some embodiments, the first surface of the substrate is a surface at the bottom of a high-aspect ratio structure (e.g., a trench), the second surface of the substrate is a surface at the top of the high-aspect ratio structure (e.g., a trench), and the third surface of the substrate is a surface on the side of the high-aspect ratio structure (e.g., a trench). As disclosed herein, non-limiting examples of high-aspect ratio structures include, for example and without limitation, at least one of a trench, a plenum, a cavity, a hole, a channel, or any combination thereof. It will be appreciated that other structures would have high-aspect ratios and thus these shall not be limiting.

As used herein, the term “metal” refers to at least one of an alkali metal, an alkaline earth metal, a transition metal, a post-transition metal, or any combination thereof. In some embodiments, the metal comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof. The charge(s) of the metal cations are known and, for simplicity, thus are not repeated here; however, it will be appreciated that the metal cations can have any known charge.

Some embodiments relate to metal carbide films and related devices and related methods. Some deposition processes can damage underlying structures. As disclosed herein, introducing a metal carbide film during a vapor deposition process can reduce or prevent damage to underlying structures used for semiconductor fabrication. The metal carbide film may provide a barrier layer to reduce or prevent damage to the underlying structure. The metal carbide film may provide a nucleation layer for a subsequent metal layer added to the metal carbide film.

Examples of vapor deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Some embodiments relate to a device. In some embodiments, the device comprises a substrate. The substrate may comprise a substrate useful for microelectronic applications and/or semiconductor applications. In some embodiments, the substrate comprises at least one of a silicon, a silicon oxide, a silicon on insulator (SOI), a carbon doped silicon oxide, an aluminum oxide, a silicon nitride, a doped silicon, a germanium, a gallium arsenide, a glass, a sapphire, a metal, a metal nitride, a metal alloy, or any combination thereof. In some embodiments, the substrate comprises a semiconductor. In some embodiments, the substrate comprises at least one of titanium, titanium nitride, tungsten, tungsten nitride, tantalum, tantalum nitride, or any combination thereof. In some embodiments, the substrate comprises aluminum oxide. In some embodiments, the substrate may comprise at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

In some embodiments, the substrate has at least one structure with an aspect ratio of at least 10:1. For example, in some embodiments, the substrate has at least one structure with an aspect ratio of at least 10:1, at least 20:1, at least 30:1, at least 40:1, at least 50:1, at least 60:1, at least 70:1, at least 80:1, or at least 90:1. In some embodiments, the substrate has at least one structure with an aspect ratio of 10:1 to 100:1, 10:1 to 90:1, 10:1 to 80:1, 10:1 to 70:1, 10:1 to 60:1, 10:1 to 50:1, 10:1 to 40:1, 10:1 to 30:1, 10:1 to 20:1, 20:1 to 100:1, 30:1 to 100:1, 40:1 to 100:1, 50:1 to 100:1, 60:1 to 100:1, 70:1 to 100:1, 80:1 to 100:1, or 90:1 to 100:1. In some embodiments, the at least one structure and the substrate are a single unitary piece. In some embodiments, the at least one structure and the substrate are separately manufactured and assembled together.

The aspect ratio of the structure can refer to a ratio of two of a width, a depth, a height, a length, or a diameter, in any combination. In some embodiments, for example, the aspect ratio refers to the ratio of a depth of a circular hole (e.g., a pore, etc.) to a diameter of the circular hole (e.g., the pore, etc.). In some embodiments, the aspect ratio refers to the ratio of a depth of a non-circular hole (e.g., a trench, etc.) to a width of the non-circular hole (e.g., the trench, etc.).

In some embodiments, the substrate is a high-aspect ratio substrate. For example, in some embodiments, a high-aspect ratio substrate comprises a substrate having at least one structure with a high-aspect ratio. In some embodiments, the substrate can have a plurality of structures, wherein each of the plurality of structures has a high-aspect ratio. The number of structures having a high-aspect ratio is not particularly limited. The at least one structure is not particularly limited and can include any structure having a high-aspect ratio as disclosed herein. In some embodiments, the at least one structure comprises at least one of a trench, a plenum, a cavity, a hole, a channel, or any combination thereof. Although high-aspect ratio structures are disclosed herein, it will be appreciated that embodiments disclosed herein also include substrates without high-aspect ratio structures.

In some embodiments, the device comprises a metal carbide film located on the substrate. In some embodiments, the metal carbide film comprises at least one of a molybdenum, a tungsten, or any combination thereof. In some embodiments, the metal carbide film comprises a molybdenum. In some embodiments, the metal carbide film comprises a tungsten.

In some embodiments, the metal carbide film is derived from a metal chloride precursor. In some embodiments, the metal chloride precursor comprises at least one of a molybdenum dichloride dioxide, a molybdenum pentachloride, a molybdenum hexachloride, a molybdenum oxytetrachloride, a tungsten hexachloride, a tungsten pentachloride, a tungsten oxytetrachloride, or any combination thereof. In some embodiments, the metal chloride precursor comprises a molybdenum dichloride dioxide. In some embodiments, the metal chloride precursor comprises a molybdenum pentachloride. In some embodiments, the metal chloride precursor comprises a molybdenum hexachloride. In some embodiments, the metal chloride precursor comprises a molybdenum oxytetrachloride. In some embodiments, the metal chloride precursor comprises a tungsten hexachloride. In some embodiments, the metal chloride precursor comprises a tungsten pentachloride. In some embodiments, the metal chloride precursor comprises a tungsten oxytetrachloride. In some embodiments, the metal chloride precursor comprises a metal oxyhalide precursor. In some embodiments, the metal oxyhalide precursor comprises a metal oxychloride precursor.

In some embodiments, the metal carbide film is derived from at least one of an alkane, an alkene, an alkyne, or any combination thereof. In some embodiments, the metal carbide film is derived from an alkane. In some embodiments, the metal carbide film is derived from an alkene. In some embodiments, the metal carbide film is derived from an alkyne. In some embodiments, the alkane comprises a methane. In some embodiments, the alkyne comprises at least one of a propyne, an acetylene, or any combination thereof.

In some embodiments, the metal carbide film comprises a residual chlorine component. In some embodiments, the residual chlorine component is derived from the metal chloride precursor.

In some embodiments, the metal carbide film comprises 0.01% to 5% of the residual chlorine component based on the total composition of the metal carbide film, or any range or subrange between 0.01% to 5%. In some embodiments, for example, the residual chlorine component comprises 0.1% to 4%, 0.5% to 3%, or 1% to 2% based on the total composition of the metal carbide film. In some embodiments, the residual chlorine component comprises 0.1% to 5%, 0.5% to 5%, 1% to 5%, 2% to 5%, 3% to 5%, or 4% to 5% based on the total composition of the metal carbide film. In some embodiments, the residual chlorine component comprises 0.01% to 4%, 0.01% to 3%, 0.01% to 2%, 0.01% to 1%, 0.01% to 0.5%, or 0.01% to 0.1% based on the total composition of the metal carbide film.

In some embodiments, the metal carbide film has a carbon content of at least 10% based on a total composition of the metal carbide film. In some embodiments, the metal carbide film has a carbon content of 10% to 99% based on a total composition of the metal carbide film, or any range or subrange between 10% to 99%. In some embodiments, for example, the metal carbide film has a carbon content of 15% to 95%, 20% to 90%, 35% to 85%, 40% to 80%, 45% to 75%, 50% to 70%, or 55% to 65% based on a total composition of the metal carbide film. In some embodiments, the metal carbide film has a carbon content of 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, or 95% to 99% based on a total composition of the metal carbide film. In some embodiments, for example, the metal carbide film has a carbon content of 10% to 95%, 10% to 90%, 10% to 85%, 10% to 80%, 10% to 75%, 10% to 70%, 10% to 65%, 10% to 60%, 10% to 55%, 10% to 50%, 10% to 45%, 10% to 40%, 10% to 35%, 10% to 30%, 10% to 25%, 10% to 20%, or 10% to 15% based on a total composition of the metal carbide film.

In some embodiments, the carbon content may be increased or decreased by varying the duration of a dose of the carbon content application to the metal carbide film. In some embodiments, the carbon content may be increased or decreased by varying the pressure of the vapor deposition process.

In some embodiments, the metal carbide film has a thickness of 10 Angstroms (Å) to 30 Angstroms, or any range or subrange between 10 Å and 30 Å. In some embodiments, the metal carbide film has a thickness of 10 Å to 25 Å, 10 Å to 20 Å, 10 Å to 15 Å, 15 Å to 30 Å, 15 Å to 25 Å, 15 Å to 20 Å, 15 Å to 25 Å.

In some embodiments, the metal carbide film has a step coverage of at least 50%. For example, in some embodiments, the metal carbide film has a step coverage of at least 50%, at least 55%, at least 60%, at least 65%, at least 70%, at least 75%, at least 80%, at least 85%, at least 90%, at least 95%, or greater. In some embodiments, the film has a step coverage of 50% to 100%, or any range or subrange between 50% and 100%. For example, in some embodiments, the metal carbide film has a step coverage of 55% to 95%, 60% to 90%, 65% to 85%, or 70% to 80%. In some embodiments, the metal carbide film has a step coverage of 50% to 95%, 50% to 90%, 50% to 85%, 50% to 80%, 50% to 75%, 50% to 70%, 50% to 65%, 50% to 60%, or 50% to 55%. In some embodiments, the metal carbide film has a step coverage of 55% to 100%, 60% to 100%, 65% to 100%, 70% to 100%, 75% to 100%, 80% to 100%, 85% to 100%, 90% to 100%, or 95% to 100%.

In some embodiments, the metal carbide film has a step coverage of at least 90%. For example, in some embodiments, the metal carbide film has a step coverage of at least 90%, at least 91%, at least 92%, at least 93%, at least 94%, at least 95%, at least 96%, at least 97%, at least 98%, at least 99%, or greater. In some embodiments, the metal carbide film has a step coverage of 90% to 100%, or any range or subrange between 90% and 100%. For example, in some embodiments, the metal carbide film has a step coverage of 91% to 99%, 92% to 98%, 93% to 97%, or 94% to 96%. In some embodiments, the metal carbide film has a step coverage of 90% to 99%, 90% to 98%, 90% to 97%, 90% to 96%, 90% to 95%, 90% to 94%, 90% to 93%, 90% to 92%, or 90% to 91%. In some embodiments, the metal carbide film has a step coverage of 91% to 100%, 92% to 100%, 93% to 100%, 94% to 100%, 95% to 100%, 96% to 100%, 97% to 100%, 98% to 100%, or 99% to 100%.

In some embodiments, the device comprises a metal layer located on the metal carbide film. In some embodiments, the metal layer comprises at least one of a molybdenum layer, a tungsten layer, or any combination thereof. In some embodiments, the metal layer comprises a molybdenum layer. In some embodiments, the metal layer comprises a tungsten layer.

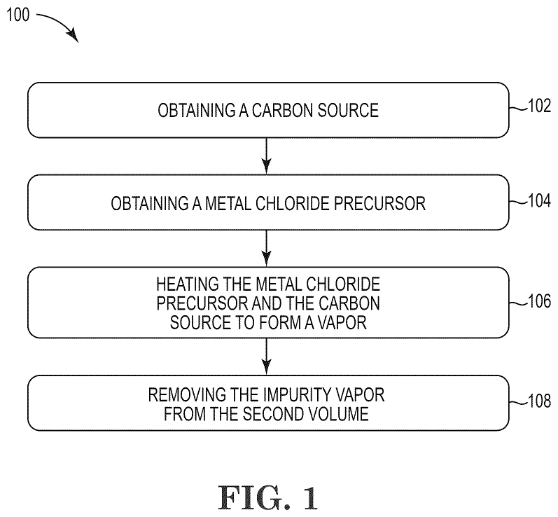

FIG. 1 is a flowchart of a method for forming a metal carbide film, according to some embodiments. As shown in FIG. 1, the method for forming a metal carbide film may comprise one or more of the following steps: obtaining a carbon source 102; obtaining a metal chloride precursor 104; heating the metal chloride precursor and the carbon source to form a vapor 106; and contacting a substrate with the vapor to form a metal carbide film 108.

At step 102, in some embodiments, the method comprises the step of obtaining a carbon source. In some embodiments, the carbon source comprises at least one of an alkane, an alkene, an alkyne, or any combination thereof. In some embodiments, the alkane comprises at least one of a methane, ethane, propane, butane, or any combination thereof. In some embodiments, the alkyne comprises at least one of a propyne, an acetylene, or any combination thereof.

At step 104, in some embodiments, the method comprises the step of obtaining a metal chloride precursor. In some embodiments, the metal chloride precursor comprises at least one of a molybdenum, a tungsten, or any combination thereof. In some embodiments, the metal chloride precursor comprises at least one of a molybdenum dichloride dioxide, a molybdenum oxytetrachloride, a molybdenum pentachloride, a tungsten hexachloride, a tungsten pentachloride, a tungsten oxytetrachloride, or any combination thereof. In some embodiments, the metal chloride precursor comprises a metal oxyhalide precursor. In some embodiments, the metal oxyhalide precursor comprises a metal oxychloride precursor.

At step 106, in some embodiments, the method comprises the step of heating the metal chloride precursor and the carbon source to form a vapor. In some embodiments, the heating may comprise heating a container comprising the metal chloride precursor and the carbon source. In some embodiments, the heating comprises heating the metal chloride precursor and the carbon source in a deposition chamber in which the vapor deposition process is performed. In some embodiments, the heating comprises operating a vapor delivery system comprising the metal chloride precursor and the carbon source. In some embodiments, the heating comprises heating to a temperature sufficient to vaporize the metal chloride precursor and the carbon source to form the vapor. In some embodiments, the heating comprises heating to a temperature below a decomposition temperature of at least one of the metal chloride precursors, the carbon source, or any combination thereof.

At step 108, in some embodiments, the method comprises the step of contacting a substrate with the vapor to form a metal carbide film. In some embodiments, the contacting comprises bringing the substrate and the vapor into close or immediate proximity to form the metal carbide film. In some embodiments, the contacting comprises bringing the substrate and the vapor into direct physical contact to form the metal carbide film. In some embodiments, the contacting comprises adding the substrate to the vapor, or vice versa to form the metal carbide film. In some embodiments, the contacting comprises mixing the substrate and the vapor to form the metal carbide film. In some embodiments, the contacting comprises stirring the substrate and the vapor to form the metal carbide film. In some embodiments, the contacting comprises agitating the substrate and the vapor to form the metal carbide film. In some embodiments, the contacting comprises flowing the vapor through a deposition chamber containing the substrate to form the metal carbide film. In some embodiments, the contacting comprises flowing the vapor over the substrate to form the metal carbide film. In some embodiments, the contacting comprises shaking the vapor on the substrate to form the metal carbide film. In some embodiments, the contacting proceeds under conditions sufficient for vapor deposition.

In some embodiments, the conditions sufficient for vapor deposition may comprise a deposition temperature. In some embodiments, the deposition temperature may be a temperature less than the thermal decomposition temperature of the vapor. In some embodiments, the deposition temperature may be sufficiently high to reduce or avoid condensation of the vapor. In some embodiments, the substrate may be heated to the deposition temperature. In some embodiments, the chamber or other vessel in which the substrate is contacted with the vapor is heated to the deposition temperature. In some embodiments, the vapor may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

In some embodiments, the conditions sufficient for vapor deposition may comprise a deposition pressure. In some embodiments, the deposition pressure may comprise a vapor pressure of the vapor. In some embodiments, the deposition pressure may comprise a chamber pressure.

The deposition pressure may be a pressure of 0.5 Torr to 500 Torr, or any range or subrange between 0.5 Torr and 500 Torr. For example, in some embodiments, the deposition pressure may be a pressure of 1 Torr to 450 Torr, 5 Torr to 400 Torr, 10 Torr to 350 Torr, 50 Torr to 300 Torr, 100 Torr to 250 Torr, or 150 Torr to 200 Torr. In some embodiments, the deposition pressure may be a pressure of 1 Torr to 500 Torr, 5 Torr to 500 Torr, 10 Torr to 500 Torr, 50 Torr to 500 Torr, 100 Torr to 500 Torr, 150 Torr to 500Torr, 200 Torr to 500 Torr, 250 Torr to 500 Torr, 300 Torr to 500 Torr, 350 Torr to 500 Torr, 400 Torr to 500 Torr, or 450 Torr to 500 Torr. In some embodiments, the deposition pressure may be a pressure of 0.5 Torr to 450 Torr, 0.5 Torr to 400 Torr, 0.5 Torr to 350 Torr, 0.5 Torr to 300 Torr, 0.5 Torr to 250 Torr, 0.5 Torr to 200 Torr, 0.5 Torr to 150 Torr, 0.5 Torr to 100 Torr, 0.5 Torr to 50 Torr, 0.5 Torr to 10 Torr, 0.5 Torr to 5 Torr, or 0.5 Torr to 1 Torr.

In some embodiments, in the deposition chamber, the substrate may have a temperature of 500° C. to 700° C., or any range or subrange between 500° C. and 700° C. In some embodiments, in the deposition chamber, the substrate may have a temperature of 550° C. to 650° C., 500° C. to 650° C., 500° C. to 600° C., 500° C. to 500° C., 550° C. to 700° C., 600° C. to 700° C., or 650° C. to 700° C.

In some embodiments, the carbon source may have a flow rate of 10 standard cubic centimeters per minute (SCCM) to 10000 SCCM in the deposition chamber, or any range or subrange between 10 SCCM to 10000 SCCM. In some embodiments, for example, the carbon source may have a flow rate of 50 SCCM to 9000 SCCM, 100 SCCM to 8000 SCCM, 500 SCCM to 7000 SCCM, 1000 SCCM to 6000 SCCM, 2000 SCCM to 5000 SCCM, or 3000 SCCM to 4000 SCCM in the deposition chamber. In some embodiments, the carbon source may have a flow rate 50 SCCM to 10000 SCCM, 100 SCCM to 10000 SCCM, 500 SCCM to 10000 SCCM, 1000 SCCM to 10000 SCCM, 2000 SCCM to 10000 SCCM, 3000 SCCM to 10000 SCCM, 4000 SCCM to 10000 SCCM, 5000 SCCM to 10000 SCCM, 6000 SCCM to 10000 SCCM, 7000 SCCM to 10000 SCCM, 8000 SCCM to 10000 SCCM, or 9000 SCCM to 10000 SCCM in the deposition chamber. In some embodiments, the carbon source may have a flow rate of 10 SCCM to 9000 SCCM, 10 SCCM to 8000 SCCM, 10 SCCM to 7000 SCCM, 10 SCCM to 6000 SCCM, 10 SCCM to 5000 SCCM, 10 SCCM to 4000 SCCM, 10 SCCM to 3000 SCCM, 10 SCCM to 2000 SCCM, 10 SCCM to 1000 SCCM, 10 SCCM to 500 SCCM, 10 SCCM to 100 SCCM, or 10 SCCM to 50 SCCM in the deposition chamber.

In some embodiments, the metal carbide film comprises a residual chlorine component. In some embodiments, the metal carbide film comprises 0.01% to 5% of the residual chlorine component based on the total composition of the metal carbide film, as disclosed herein.

In some embodiments, the metal carbide film has a carbon content of at least 10% based on a total composition of the metal carbide film. In some embodiments, the metal carbide film has a carbon content of 10% to 99% based on a total composition of the metal carbide film.

In some embodiments, the metal carbide film has a thickness of 10 Angstroms to 30 Angstroms. In some embodiments, the thickness of the metal carbide film may be measured by at least one of an X-ray fluorescence (XRF), X-ray fluorescence diffraction (XRD), ellipsometer, TEM or any combination thereof.

In some embodiments, the metal carbide film has a resistivity of 200 ohm-centimeter (ohm-cm) to 4000 ohm-cm. In some embodiments, for example, the metal carbide film has a resistivity of 500 ohm-cm to 3500 ohm-cm, 1000 ohm-cm to 3000 ohm-cm, or 1500 ohm-cm to 2500 ohm-cm. In some embodiments, the metal carbide film has a resistivity of 500 ohm-cm to 4000 ohm-cm, 1000 ohm-cm to 4000 ohm-cm, 1500 ohm-cm to 4000 ohm-cm, 2000 ohm-cm to 4000 ohm-cm, 2500 ohm-cm to 4000 ohm-cm, 3000 ohm-cm to 4000 ohm-cm, or 3500 ohm-cm to 4000 ohm-cm. In some embodiments, the metal carbide film has a resistivity of 200 ohm-cm to 3500 ohm-cm, 200 ohm-cm to 3000 ohm-cm, 200 ohm-cm to 2500 ohm-cm, 200 ohm-cm to 2000 ohm-cm, 200 ohm-cm to 1500 ohm-cm, 200 ohm-cm to 1000 ohm-cm, 200 ohm-cm to 500 ohm-cm, 200 ohm-cm to 400 ohm-cm, or 200 ohm-cm to 300 ohm-cm.

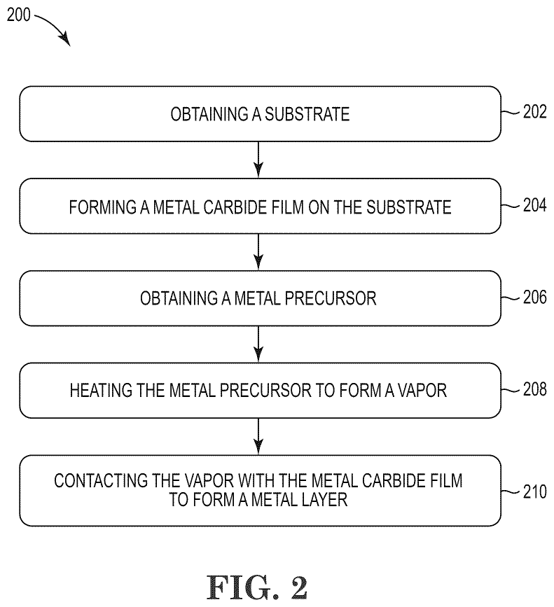

FIG. 2 is a is a flowchart of a method for forming a metal layer on a metal carbide film, according to some embodiments. As shown in FIG. 2, the method for forming a metal layer on a metal carbide film may comprise one or more of the following steps: obtaining a substrate 202; forming a metal carbide film on the substrate 204; obtaining a metal precursor 206; heating the metal precursor to form a vapor 208; and contacting the vapor with the metal carbide film to form a metal layer 210.

At step 202, in some embodiments, the method comprises the step of obtaining a substrate. The substrate may comprise a substrate useful for microelectronic applications and/or semiconductor applications. In some embodiments, the substrate comprises at least one of a silicon, a silicon oxide, a silicon on insulator (SOI), a carbon doped silicon oxide, an aluminum oxide, a silicon nitride, a doped silicon, a germanium, a gallium arsenide, a glass, a sapphire, a metal, a metal nitride, a metal alloy, or any combination thereof. In some embodiments, the substrate comprises a semiconductor. In some embodiments, the substrate comprises at least one of titanium, titanium nitride, tungsten, tungsten nitride, tantalum, tantalum nitride, or any combination thereof. In some embodiments, the substrate comprises aluminum oxide.

At step 204, in some embodiments, the method comprises the step of forming a metal carbide film on the substrate. In some embodiments, the metal carbide film comprises at least one of a molybdenum, a tungsten, or any combination thereof. In some embodiments, the metal carbide film comprises molybdenum. In some embodiments, the metal carbide film comprises a tungsten.

In some embodiments, the metal carbide film comprises a residual chlorine component as described herein. In some embodiments, the metal carbide film comprises 0.01% to 5% of the residual chlorine component based on the total composition of the metal carbide film.

In some embodiments, the metal carbide film has a carbon content of at least 10% based on a total composition of the metal carbide film. In some embodiments, the metal carbide film has a carbon content of 10% to 99% based on a total composition of the metal carbide film, or any range or subrange between 10% to 99%. In some embodiments, for example, the metal carbide film has a carbon content of 15% to 95%, 20% to 90%, 35% to 85%, 40% to 80%, 45% to 75%, 50% to 70%, or 55% to 65% based on a total composition of the metal carbide film. In some embodiments, the metal carbide film has a carbon content of 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, or 95% to 99% based on a total composition of the metal carbide film. In some embodiments, for example, the metal carbide film has a carbon content of 10% to 95%, 10% to 90%, 10% to 85%, 10% to 80%, 10% to 75%, 10% to 70%, 10% to 65%, 10% to 60%, 10% to 55%, 10% to 50%, 10% to 45%, 10% to 40%, 10% to 35%, 10% to 30%, 10% to 25%, 10% to 20%, or 10% to 15% based on a total composition of the metal carbide film.

At step 206, in some embodiments, the method comprises the step of obtaining a metal precursor. In some embodiments, the metal precursor comprises at least one of a tungsten, a molybdenum, or any combination thereof. In some embodiments, the metal precursor comprises a molybdenum. In some embodiments, the metal precursor comprises a tungsten.

At step 208, in some embodiments, the method comprises the step of heating the metal precursor to form a vapor. In some embodiments, the heating may comprise heating a container comprising the metal precursor. In some embodiments, the heating comprises heating the metal precursor in a deposition chamber in which the vapor deposition process is performed. In some embodiments, the heating comprises operating a vapor delivery system comprising the metal precursor. In some embodiments, the heating comprises heating to a temperature sufficient to vaporize the metal precursor and to form the vapor. In some embodiments, the heating comprises heating to a temperature below a decomposition temperature of the metal precursor.

At step 210, in some embodiments, the method comprises the step of contacting the vapor with the metal carbide film to form a metal layer. In some embodiments, the contacting comprises bringing the vapor and the metal carbide film into close or immediate proximity to form the metal layer. In some embodiments, the contacting comprises bringing the vapor and the metal carbide film into direct physical contact to form the metal layer. In some embodiments, the contacting comprises adding the vapor to the metal carbide film, or vice versa to form the metal layer. In some embodiments, the contacting comprises mixing the vapor and the metal carbide film to form the metal layer. In some embodiments, the contacting comprises stirring the vapor and the metal carbide film to form the metal layer. In some embodiments, the contacting comprises agitating the vapor and the metal carbide film to form the metal layer. In some embodiments, the contacting comprises flowing the vapor through a deposition chamber containing the metal carbide film on a substrate to form the metal layer. In some embodiments, the contacting comprises flowing the vapor over metal carbide film on the substrate to form the metal layer. In some embodiments, the contacting comprises shaking the vapor on the metal carbide film on the substrate to form the metal layer. In some embodiments, the contacting proceeds under conditions sufficient for vapor deposition.

In some embodiments, hydrogen may be vaporized or provided as a pressurized gas to form a hydrogen vapor to form the metal layer. In some embodiments, the hydrogen may be a co-reactant with the vapor to form the metal layer.

The flow rate of the hydrogen vapor and the pressure of hydrogen in the reaction chamber can control the purity and other qualities of the metal film. In some embodiments, the hydrogen vapor may have a flow rate of 10 SCCM to 50000 SCCM, or any range or subrange between 10 SCCM to 50000 SCCM. In some embodiments, for example, the hydrogen vapor may have a flow rate of 100 SCCM to 900 SCCM, 200 SCCM to 800 SCCM, 300 SCCM to 700 SCCM, or 400 SCCM to 600 SCCM. In some embodiments, the hydrogen vapor may have a flow rate of 100 SCCM to 1000 SCCM, 200 SCCM to 1000 SCCM, 300 SCCM to 1000 SCCM, 400 SCCM to 1000 SCCM, 500 SCCM to 1000 SCCM, 600 SCCM to 1000 SCCM, 700 SCCM to 1000 SCCM, 800 SCCM to 1000 SCCM, or 900 SCCM to 1000 SCCM. In some embodiments, for example, the hydrogen vapor may have a flow rate of 100 SCCM to 900 SCCM, 100 SCCM to 800 SCCM, 100 SCCM to 700 SCCM, 100 SCCM to 600 SCCM, 100 SCCM to 500 SCCM, 100 SCCM to 400 SCCM, 100 SCCM to 300 SCCM, 100 SCCM to 200 SCCM, or 100 SCCM to 150 SCCM.

In some embodiments, the vapor deposition process has a cycle time of 10 seconds to 5 minutes, or any range or subrange between 10 seconds to 5 minutes. In some embodiments, the vapor deposition process has a cycle time of 30 seconds to 4 minutes, 30 seconds to 3 minutes, 30 seconds to 2 minutes, or 30 seconds to 1 minute. In some embodiments, the vapor deposition process has a cycle time of 1 minute to 5 minutes, 2 minutes to 5 minutes, 3 minute to 5 minutes, or 4 minutes to 5 minutes.

In some embodiments, at least two or more metal layers may be deposited onto the substrate by dosing a carbon source to the metal carbide film, such as acetylene, purging the acetylene from the metal carbide film, depositing a metal layer to the metal carbide film, purging the metal layer, dosing hydrogen to the metal layer.

In some embodiments, a metal layer is deposited to the metal carbide film without hydrogen. In some embodiments, a metal layer is deposited to the metal carbide film with hydrogen.

In some embodiments, the metal layer comprises at least one of a molybdenum, a tungsten, or any combination thereof. In some embodiments, the metal layer comprises a molybdenum. In some embodiments, the metal layer comprises a tungsten.

In some embodiments, the metal layer has a thickness of 10 Å to 1000 Å, or any range or subrange between 10 Å and 1000 Å. In some embodiments, for example, the metal layer has a thickness of 50 Å to 900 Å, 100 Å to 800 Å, 200 Å to 700 Å, 300 Å to 600 Å, or 400 Å to 500 Å. In some embodiments, the metal layer has a thickness of 50 Å to 1000 Å, 10 Å to 1000 Å, 200 Å to 1000 Å, 300 Å to 1000 Å, 400 Å to 1000 Å, 500 Å to 1000 Å, 600 Å to 1000 Å, 700 Å to 1000 Å, 800 Å to 1000 Å, 900 Å to 1000 Å, or 950 Å to 1000 Å. In some embodiments, the metal layer has a thickness of 10 Å to 900 Å, 10 Å to 800 Å, 10 Å to 700 Å, 10 Å to 600 Å, 10 Å to 500 Å, 10 Å to 400 Å, 10 Å to 300 Å, 10 Å to 200 Å, 10 Å to 100 Å, or 10 Å to 50 Å.

Any one or more of the embodiments disclosed herein shall be understood to be combinable without departing from the scope or spirit of the disclosure.

### EXAMPLE 1

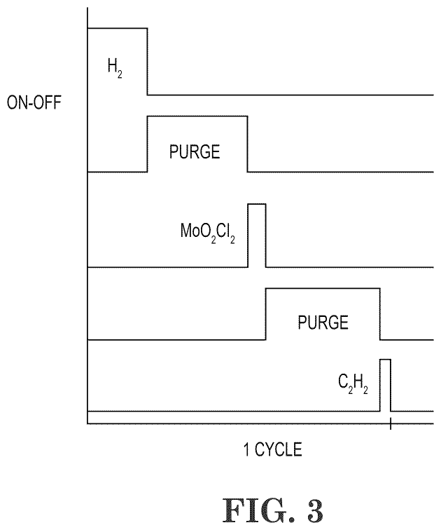

FIG. 3 is a graphical representation of an ALD metal film deposition using acetylene and hydrogen, according to some embodiments. A vapor deposition process was performed using molybdenum dichloride dioxide. Acetylene vapor was dosed to a substrate to form an acetylene film on the substrate. The chamber was then purged. Molybdenum dichloride dioxide vapor was next dosed to the substrate to form a molybdenum carbide film with residual chlorine contained therein on the substrate. The substrate having the molybdenum carbide film was then purged. Hydrogen was then dosed to the molybdenum carbide film on the substrate. The molybdenum layer was then added to the metal carbide film with the following steps. The metal carbide film was then purged. Molybdenum dichloride dioxide vapor was next dosed to the metal carbide film to form a molybdenum layer. The molybdenum layer was then purged.

### EXAMPLE 2

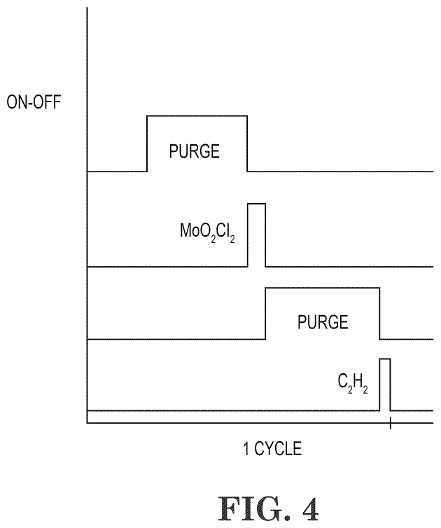

FIG. 4 is a graphical representation of an ALD metal carbide film deposition using acetylene without hydrogen, according to some embodiments. A vapor deposition process was performed using molybdenum dichloride dioxide. Acetylene vapor was dosed to a substrate to form an acetylene film on the substrate. The substrate was then purged. Molybdenum dichloride dioxide vapor was next dosed to the substrate to form a molybdenum carbide film with residual chlorine contained therein on the substrate. The substrate having the molybdenum carbide film was then purged. The molybdenum layer was then added to the metal carbide film with the following steps. Molybdenum dichloride dioxide vapor was next dosed to the metal carbide film to form a molybdenum layer. The molybdenum layer was then purged.

### EXAMPLE 3

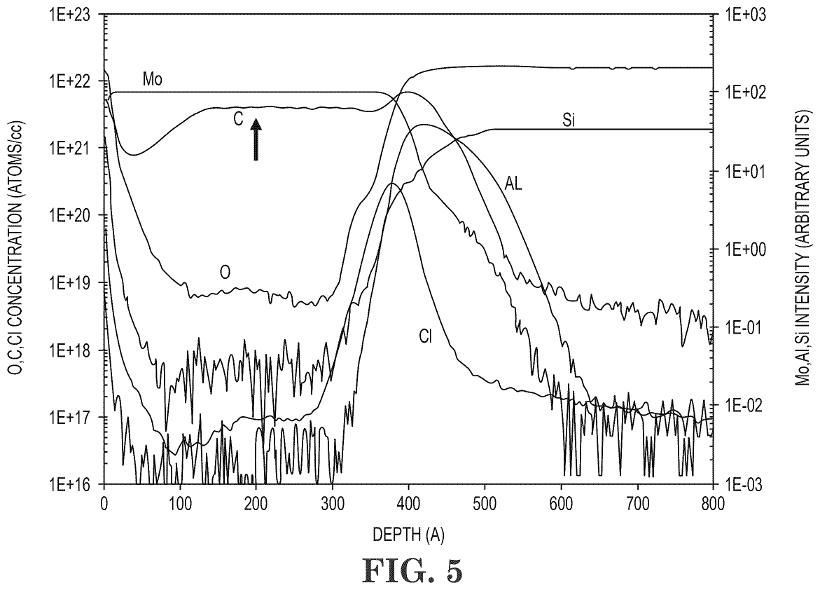

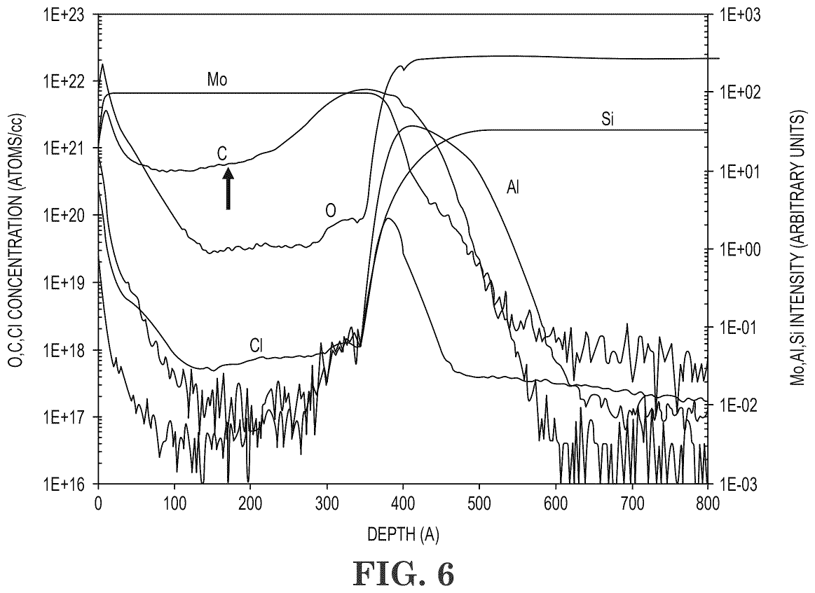

FIG. 5 is a Secondary Ion Mass Spectrometry (SIMS) showing a high concentration of carbon content in a metal carbide film along a depth, according to some embodiments. FIG. 6 is a Secondary Ion Mass Spectrometry (SIMS) showing a low concentration of carbon content in a metal carbide film along a depth, according to some embodiments. A high concentration of carbon in the metal carbide film is shown in FIG. 5 compared to a low concentration of carbon in the metal carbide film in FIG. 6 at similar depths of the molybdenum layer. The high concentration of carbon in FIG. 5 was achieved by changing the pressure during the vapor deposition.

### ASPECTS

Various Aspects are described below. It is to be understood that any one or more of the features recited in the following Aspect(s) can be combined with any one or more other Aspect(s).
Aspect 1. A device comprising:
   a substrate; and
   a metal carbide film located on the substrate,
      wherein the metal carbide film comprises:
         at least one of a molybdenum, a tungsten, or any combination thereof; and
         a residual chlorine component,
      wherein the metal carbide film has a carbon content of at least 10% based on a total composition of the metal carbide film.
Aspect 2. The device according to Aspect 1, further comprising:
   a metal layer located on the metal carbide film,
      wherein the metal layer comprises at least one of a molybdenum layer, a tungsten layer, or any combination thereof.
Aspect 3. The device according to any one of Aspects 1-2, wherein the metal carbide film has a thickness of 10 Angstroms to 30 Angstroms.
Aspect 4. The device according to any one of Aspects 1-3, wherein the metal carbide film comprises 0.01% to 5% of the residual chlorine component based on the total composition of the metal carbide film.
Aspect 5. The device according to any one of Aspects 1-4, wherein the metal carbide film has a carbon content of 10% to 99% based on a total composition of the metal carbide film.
Aspect 6. The device according to any one of Aspects 1-5, wherein the metal carbide film is derived from at least one of an alkane, an alkene, an alkyne, or any combination thereof.
Aspect 7. A method comprising:
   obtaining a carbon source;
   obtaining a metal chloride precursor,
   heating the metal chloride precursor and the carbon source to form a vapor; and
   contacting a substrate with the vapor to form a metal carbide film,
      wherein the metal carbide film comprises a residual chlorine component,
      wherein the metal carbide film has a carbon content of at least 10% based on a total composition of the metal carbide film.
Aspect 8. The method according to Aspect 7, wherein the carbon source comprises at least one of an alkane, an alkene, an alkyne, or any combination thereof.
Aspect 9. The method according to any of Aspects 7-8, wherein the metal chloride precursor comprises at least one of a molybdenum, a tungsten, or any combination thereof.
Aspect 10. The method according to any one of Aspects 7-9, wherein the metal chloride precursor comprises at least one of a molybdenum dichloride dioxide, a molybdenum oxytetrachloride, a molybdenum pentachloride, a tungsten hexachloride, a tungsten pentachloride, a tungsten oxytetrachloride, or any combination thereof.
Aspect 11. The method according to any one of Aspects 7-10, wherein the metal carbide film comprises 0.01% to 5% of the residual chlorine component based on the total composition of the metal carbide film.
Aspect 12. The method according to any one of Aspects 7-11, wherein the metal carbide film has a carbon content of 10% to 99% based on a total composition of the metal carbide film.
Aspect 13. The method according to any one of Aspects 7-12, wherein the metal carbide film has a thickness of 10 Angstroms to 30 Angstroms.
Aspect 14. A method comprising:
   obtaining a substrate;
   forming a metal carbide film on the substrate,
      wherein the metal carbide film comprises:
         at least one of a molybdenum, a tungsten, or any combination thereof; and
         a residual chlorine component,
      wherein the metal carbide film has a carbon content of at least 10% based on a total composition of the metal carbide film;
   obtaining a metal precursor;
   heating the metal precursor to form a vapor; and
   contacting the vapor with the metal carbide film to form a metal layer.
Aspect 15. The method according to Aspect 14, wherein the metal carbide film comprises 0.01% to 5% of the residual chlorine component based on the total composition of the metal carbide film.
Aspect 16. The method according to any one of Aspects 14-15, wherein the metal carbide film has a carbon content of 10% to 99% based on a total composition of the metal carbide film.
Aspect 17. The method according to any one of Aspects 14-16, wherein the metal layer comprises at least one of a molybdenum, a tungsten, or any combination thereof.
Aspect 18. The method according to any one of Aspects 14-17, wherein the metal carbide film has a thickness of 10 Angstroms to 30 Angstroms.
Aspect 19. The method according to any one of Aspects 14-18, wherein the metal layer has a thickness of 10 Angstroms to 1000 Angstroms.
Aspect 20. The method according to any one of Aspects 14-19, wherein the metal carbide film has a thickness of 5 Angstroms to 50 Angstroms.

What is claimed is:

1. A device comprising:
a substrate; and
a metal carbide film located on the substrate,
wherein the metal carbide film comprises:
at least one of a molybdenum, a tungsten, or any combination thereof; and
a residual chlorine component,
wherein the metal carbide film has a carbon content of at least 10% based on a total composition of the metal carbide film.

2. The device of claim 1, further comprising:
a metal layer located on the metal carbide film,
wherein the metal layer comprises at least one of a molybdenum layer, a tungsten layer, or any combination thereof.

3. The device of claim 1, wherein the metal carbide film has a thickness of 10 Angstroms to 30 Angstroms.

4. The device of claim 1, wherein the metal carbide film comprises 0.01% to 5% of the residual chlorine component based on the total composition of the metal carbide film.

5. The device of claim 1, wherein the metal carbide film has a carbon content of 10% to 99% based on a total composition of the metal carbide film.

6. The device of claim 1, wherein the metal carbide film is derived from at least one of an alkane, an alkene, an alkyne, or any combination thereof.

7. A method comprising:
obtaining a carbon source;
obtaining a metal chloride precursor,
heating the metal chloride precursor and the carbon source to form a vapor; and
contacting a substrate with the vapor to form a metal carbide film,
wherein the metal carbide film comprises a residual chlorine component,
wherein the metal carbide film has a carbon content of at least 10% based on a total composition of the metal carbide film.

8. The method of claim 7, wherein the carbon source comprises at least one of an alkane, an alkene, an alkyne, or any combination thereof.

9. The method of claim 7, wherein the metal chloride precursor comprises at least one of a molybdenum, a tungsten, or any combination thereof.

10. The method of claim 7, wherein the metal chloride precursor comprises at least one of a molybdenum dichloride dioxide, a molybdenum oxytetrachloride, a molybdenum pentachloride, a tungsten hexachloride, a tungsten pentachloride, a tungsten oxytetrachloride, or any combination thereof.

11. The method of claim 7, wherein the metal carbide film comprises 0.01% to 5% of the residual chlorine component based on the total composition of the metal carbide film.

12. The method of claim 7, wherein the metal carbide film has a carbon content of 10% to 99% based on a total composition of the metal carbide film.

13. The method of claim 7, wherein the metal carbide film has a thickness of 10 Angstroms to 30 Angstroms.

14. A method comprising:
obtaining a substrate;
forming a metal carbide film on the substrate,
wherein the metal carbide film comprises:
at least one of a molybdenum, a tungsten, or any combination thereof; and
a residual chlorine component,
wherein the metal carbide film has a carbon content of at least 10% based on a total composition of the metal carbide film;
obtaining a metal precursor;
heating the metal precursor to form a vapor; and
contacting the vapor with the metal carbide film to form a metal layer.

15. The method of claim 14, wherein the metal carbide film comprises 0.01% to 5% of the residual chlorine component based on the total composition of the metal carbide film.

16. The method of claim 14, wherein the metal carbide film has a carbon content of 10% to 99% based on a total composition of the metal carbide film.

17. The method of claim 14, wherein the metal layer comprises at least one of a molybdenum, a tungsten, or any combination thereof.

18. The method of claim 14, wherein the metal carbide film has a thickness of 10 Angstroms to 30 Angstroms.

19. The method of claim 14, wherein the metal layer has a thickness of 10 Angstroms to 1000 Angstroms.

20. The method of claim 14, wherein the metal carbide film has a thickness of 5 Angstroms to 50 Angstroms.
